(19) United States
(12) Patent Application Publication
(10) Pub. No.: US 2015/0076463 A1
(43) Pub. Date: Mar. 19, 2015

(54) ORGANIC EL DEVICE AND MANUFACTURING METHOD THEREFOR

(71) Applicant: Hidetaka Ohazama, Yonezawa-shi (JP)

(72) Inventor: Hidetaka Ohazama, Yonezawa-shi (JP)

(73) Assignees: Tohoku Pioneer Corporation, Tendo-shi, Yamagata (JP); Pioneer Corporation, Kawasaki-shi, Kanagawa (JP)

(21) Appl. No.: 14/380,922

(22) PCT Filed: Mar. 1, 2012
(86) PCT No.: PCT/JP2012/055283

§ 371 Date: Aug. 25, 2014

(51) Int. Cl. H01L 51/52; H01L 51/56

(52) U.S. Cl. CPC H01L 51/5253; H01L 51/56; H01L 51/5246; H01L 51/5209
USPC 257/40; 438/26

(57) ABSTRACT

In an organic EL device, a risk of a short circuit between adjacent terminals in a connection space on a substrate can be reduced. An organic EL device includes a substrate, one or a plurality of organic EL elements formed on the substrate, a plurality of connection terminals provided on the substrate and electrically connected to electrodes of the organic EL elements, an insulating cover layer that covers the connection terminals and the substrate between the connection terminals, and a mounted component mounted via an anisotropic conducive layer and including terminals to be connected electrically connected to the connection terminals. The anisotropic conductive layer includes conductive particulates that electrically connect the connection terminals and the terminals to be connected. The conductive particulates electrically connect the connection terminals and the terminals to be connected piercing through the cover layer.

### TECHNICAL FIELD

The present invention relates to an organic EL device and a manufacturing method therefor.

### BACKGROUND ART

A self-light-emitting device (an organic EL device) including an organic EL element is usable in various applications and models, for example, as various display devices used in a display screen of a cellular phone, a monitor screen of a vehicle mounted or home-use electronic apparatus, an information display screen of a personal computer or a television receiver, a lighting panel for advertisement, and the like, and as various light sources used in a scanner, a printer, and the like, as lighting devices used in general lighting, a backlight of a liquid crystal display device, and the like, and as a device for optical communication that makes use of a photoelectric conversion function.

In the organic EL device, the organic EL element is arranged on a substrate. The organic EL element is arranged in a sealed region hermetically sealed by a sealing member. An electrode of the organic EL element is connected to an extraction electrode drawn out to the outside of the sealing region. The extraction electrode is connected to a driving element and a wiring substrate in a connection space provided at the peripheral edge of the substrate.

For connection of the extraction electrode and the driving element and the wiring substrate, an ACF (Anisotropic Conductive Film) method or a eutectic method is generally adopted. In the conventional technique described in Patent Document 1, a circuit pattern connected to an organic EL element is formed on a substrate on the outer side of a sealing member. An IC chip is mounted (chip on glass) and a flexible printed board is mounted (flexible print circuit) on the circuit pattern. Resin is applied to an exposed portion of the circuit pattern.

### RELATED ART DOCUMENT

### Patent Document

[Patent Document 1] Japanese Patent Application Laid-open No. 2009-289615

### SUMMARY OF THE INVENTION

### Problems to be Solved by the Invention

In the organic EL device, an element forming space, in which the organic EL element on the substrate is arranged, is an effective space for obtaining light emission. A space on the outer side of the element forming space is a so-called marginal space in which light emission is not obtained. When the organic EL device is mounted in a limited space in an electronic apparatus, an automobile, or the like, it is requested to form the element forming space, which is the effective space, as large as possible and form the marginal space as narrow as possible.

In order to narrow the marginal space in the organic EL device, the connection space on the outer side of the sealing region has to be narrowed. When the connection space is narrowed, in chip on glass or flexible print circuit mounting performed using an anisotropic conductive layer, conductive particulates flow from a connection region where a connection terminal is present to a non-connection region where the connection terminal is absent in the narrow connection space. Overcrowding of the conductive particulates in the non-connection region occurs. Consequently, a problem occurs in which the conductive particulates lie in a row in the non-connection region and a short-circuit failure tends to occur between adjacent terminals in the connection space. The problem of such a short circuit between the adjacent terminals becomes more conspicuous when an electrode interval of the organic EL element is set dense in order to obtain high resolution.

On the other hand, in the connection space, the chip on glass or flexible print circuit mounting can be performed by drawing out and exposing the connection terminal from the sealing region. On the other hand, when the sealing of the organic EL element is performed by a sealing film, in order to expose the connection terminal of the connection space, it is necessary to form, prior to a film forming process for the sealing film, a mask pattern for covering the connection space or remove (lift off) the sealing film on the connection space after the film forming process for the sealing film. In either method, a separate process for exposing the connection terminal is necessary in addition to the film forming process for the sealing film. A facility for executing the process is necessary. Therefore, a problem occurs in which extension of a takt time and an increase in manufacturing costs is inevitable.

It is an example of an object of the present invention to take measures against such problems. That is, it is an object of the present invention to, in an organic EL device, for example, make it possible to reduce a risk of a short circuit between adjacent terminals in a connection space on a substrate and, when sealing of an organic EL element is performed by a sealing film, make it possible to eliminate a process and a facility required for exposing a connection terminal in the connection space and avoiding extension of a takt time and an increase in manufacturing costs.

### Means for Solving the Problems

In order to attain such an object, an organic EL device and a manufacturing method therefor according to the present invention include at least configurations explained below.

An organic EL device including: a substrate; one or a plurality of organic EL elements formed on the substrate; a plurality of connection terminals provided on the substrate and electrically connected to electrodes of the organic EL elements; an insulating cover layer covering the connection terminals and the substrate between the connection terminals; and a mounted component mounted via an anisotropic conducive layer and including terminals to be connected electrically to the connection terminals, wherein the anisotropic conductive layer includes conductive particulates that electrically connect the connection terminals and the terminals to be connected, and the conductive particulates electrically connect the connection terminals and the terminals to be connected piercing through the cover layer.

A manufacturing method for an organic EL device including: a step of forming an organic EL element on a substrate and forming, in a connection space on the substrate, a connection terminal connected to an electrode of the organic EL element; a step of forming an insulating cover layer covering the connection terminal and the substrate in the connection space; and a mounting step of mounting a mounted component in the connection space via an anisotropic conductive layer, wherein, in the mounting step, with the substrate and the mounted components being compression-bonded, conductive particulates of the anisotropic conductive layer electrically connect the connection terminal and a terminal to be connected of the mounted component piercing through the cover layer.

### BRIEF DESCRIPTION OF THE DRAWINGS

FIG. 1 is an explanatory diagram showing the overall configuration of an organic EL device according to an embodiment of the present invention (FIG. 1(a) is an example of chip on glass mounting and FIG. 1(b) is an example of flexible print circuit mounting.)

FIG. 2 is a partial sectional view of the organic EL device according to the embodiment of the present invention and shows an X-X sectional view in FIG. 1(a).

FIG. 3 shows an X1-X1 sectional view in FIG. 2 and also is an enlarged explanatory diagram of a connection structure in a connection space.

FIG. 4 is an explanatory diagram schematically showing preferred form examples of a conductive particulate in the embodiment of the present invention.

FIG. 5 is an explanatory diagram showing a manufacturing method for the organic EL device according to the embodiment of the present invention.

FIG. 6 is an explanatory diagram showing a manufacturing method for the organic EL device according to the embodiment of the invention.

### BEST MODE FOR CARRYING OUT THE INVENTION

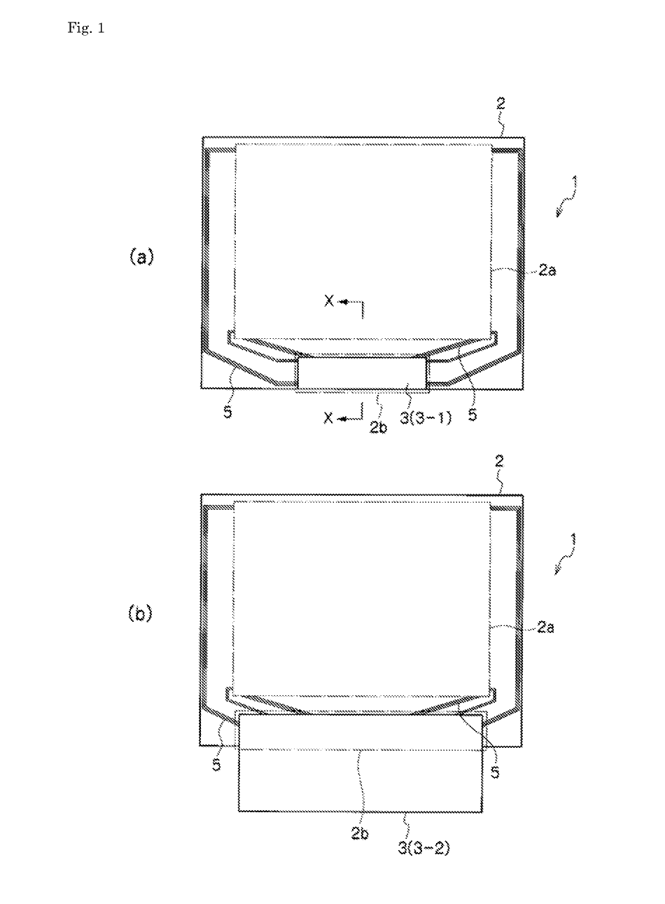

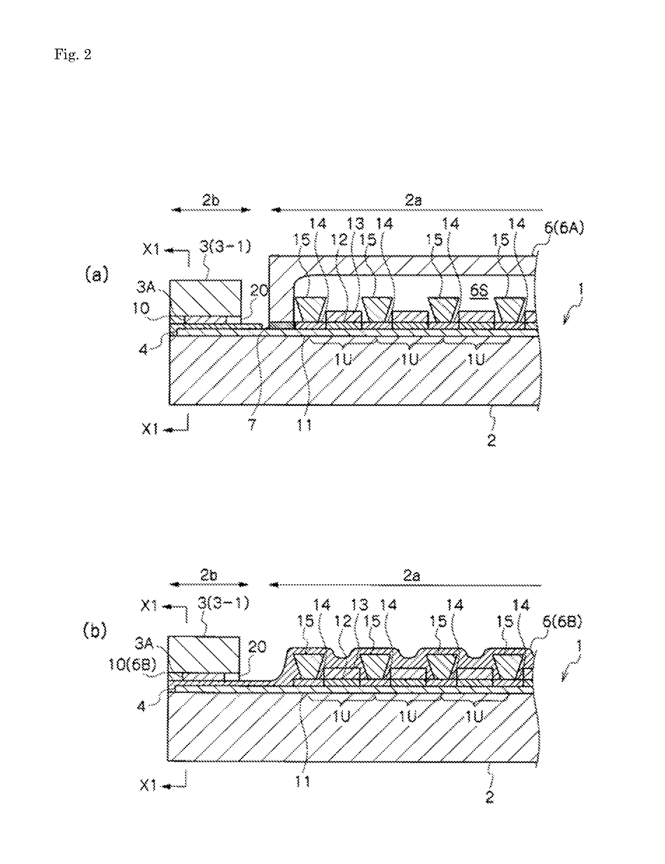

An embodiment of the present invention is explained below with reference to the accompanying drawings. The embodiment of the present invention includes contents shown in the figures but is not limited to the contents. FIG. 1 is an explanatory diagram showing the overall configuration of an organic EL device according to an embodiment of the present invention (FIG. 1(a) is an example of chip on glass mounting and FIG. 1(b) is an example of flexible print circuit mounting.) FIG. 2 is a partial sectional view of the organic EL device according to the embodiment of the present invention and shows an X-X sectional view in FIG. 1(a). FIGS. 2(a) and 2(b) respectively show sectional views of different form examples.

An organic EL device 1 includes a substrate 2, one or a plurality of organic EL elements 1U formed on the substrate 2, and a mounted component 3 mounted on the substrate 2. Examples of the mounted component 3 include a semiconductor chip 3-1 illustrated in FIG. 1(a) and a flexible printed substrate 3-2 illustrated in FIG. 1(b). However, the mounted component 3 is not limited to these components.

On the substrate 2, an element formation space 2a, in which the organic EL elements 1U are formed, is provided. A connection space 2b is provided on the outer side of the element formation space 2a. In the connection space 2b, a plurality of connection terminals 4 electrically connected to electrodes (lower electrodes 11 or upper electrodes 13) of the organic EL elements 1U are provided. The connection terminals 4 are electrically connected to the electrodes (the lower electrodes 11 or the upper electrodes 13) of the organic EL elements 1U in the element formation space 2a via extraction wires 5, auxiliary electrodes, and the like. The plurality of connection terminals connected to the electrodes of the organic EL elements include a connection terminal connected to a TFT in an organic EL device of an active matrix driving system. In this case, the connection terminal is indirectly connected to an organic EL element via the TFT. The connection terminals 4 may be plural layer structures subjected to treatment such as plating with gold, copper, or the like. Consequently, it is possible to realize a reduction in resistance of the wires by the connection terminals 4.

The organic EL elements 1U formed in the element formation space 2a on the substrate 2 are hermetically sealed between the substrate 2 and the sealing member 6. The sealing member 6 may be a sealing member (hollow seal) in which a seal substrate 6A shown in FIG. 2(a) is used and the substrate 2 and the seal substrate 6A are stuck together via a bonding layer 7 to form a sealing space 6S between the substrate 2 and the seal substrate 6A or may be a sealing member (film sealing) in which a sealing film shown in FIG. 2(b) is used and a sealing film 6B covers components of the organic EL elements 1U without a space.

As shown in FIGS. 2(a) and 2(b), the organic EL element 1U is laminated on the substrate 2. The organic EL element 1U includes at least the lower electrode 11, an organic layer 12, and the upper electrode 13. In the illustrated example, the lower electrode 11 is film-formed on the substrate 2, the organic layer 12 is film-formed on the lower electrode 11, and the upper electrode 13 is film-formed on the organic layer 12. Several film forming layers may be present between the substrate 2 and the lower electrode 11. Other layers may be laminated among the lower electrode 11, the organic layer 12, and the upper electrode 13. The organic layer 12 is formed by one light-emitting layer or formed by several functional layers (a hole injection/transport layer, a light-emitting layer, an electron injection/transport layer, etc.) for light emission. In the illustrated example, the organic EL element 1U includes an insulating layer 14 that insulates a light-emitting region as an insulated portion for each of the organic EL elements 1U on the lower electrode 11 and a partition wall 15 that is formed on the insulating layer 14 and insulates the upper electrode 13 as an insulated portion. The illustrated configuration example of the organic EL element 1U is an example. A driving system for the organic EL element 1U in the embodiment of the present invention may be either a passive driving system or an active driving system.

An insulating cover layer 10 that covers the connection terminals 4 and the substrate 2 between the connection terminals 4 is provided in the connection space 2b on the substrate 2. In an example shown in FIG. 2(a), the cover layer 10 is independently formed in the connection space 2b. In an example shown in FIG. 2(b), the cover layer 10 is formed by extending the sealing film 6B. In this example, by forming the sealing film 6B over the entire substrate 2, it is possible to form the cover layer 10 in the connection space 2b. In the connection space 2b, the mounted component 3 is mounted via the anisotropic conductive layer 20. The connection terminals 4 and terminals to be connected 3A of the mounted component 3 are electrically connected via the conductive particulates of the anisotropic conductive layer 20. When the connection terminals 4 are electrically connected, the connection terminals 4 can be formed as plural layer structures subjected to treatment such as plating with gold, copper, or the like. In this case, the surface of the connection terminal 4 is covered with the cover layer 10. Therefore, it is possible to actively realize a reduction in resistance of the terminals by using corrosive metal such as gold on the surfaces of the connection terminals 4.

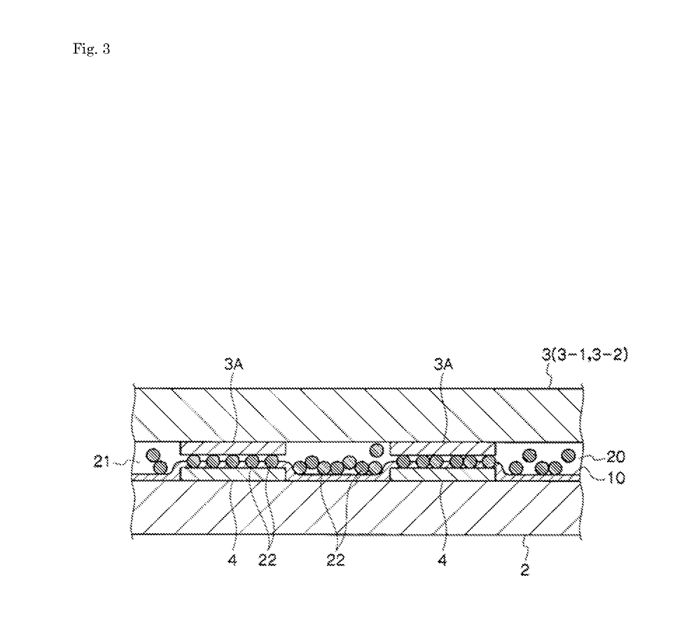

FIG. 3 is an X1-X1 sectional view in FIG. 2 and is an enlarged explanatory diagram showing a connection structure in the connection space. In the connection space 2b, the anisotropic conductive layer 20 interposed between the substrate 2 and the mounted component 3 includes a joining layer 21 that physically joins the substrate 2 and the mounted component 3 and conductive particulates 22 dispersed in the joining layer 21. As the anisotropic conductive layer 20, a thermo-compression bonding anisotropic conductive film (ACF), a layer formed by dispersing the conductive particulates 22 in the joining layer 21 made of light curing resin, and the like can be used.

Before the compression bonding of the substrate 2 and the mounted component 3 is performed, the connection terminals 4 in the connection space 2b is individually covered with the insulating cover layer 10 to be insulated as an insulated portion. When the anisotropic conductive layer 20 is formed on the cover layer 10 and the substrate 2 and the mounted component 3 are compression-bonded, the cover layer 10 is pierced through by the conductive particulates 22 held between the connection terminals 4 of the substrate 2 and the terminals to be connected 3A of the mounted component 3. Consequently, in connection regions where the connection terminals 4 and the terminals to be connected 3A face each other, the connection terminals 4 and the terminals to be connected 3A are electrically connected in parts where the conductive particulates 22 pierce through the cover layer 10.

When the connection terminals 4 and the terminals to be connected 3A are electrically connected, a press-contact force is not directly applied to the conductive particulates 22 in regions to be connected between the connection terminals 4 adjacent to each other or between the terminals to be connected 3A. Therefore, the conductive particulates 22 do not pierce through the cover layer 10.

In the organic EL device 1 including such a configuration, even when the connection space 2b is narrowed to narrow the marginal space and the density of the conductive particulates 22 increases in the region to be connected of the connection space 2b, since the side surfaces of the respective connection terminals 4 are covered with the insulating cover layer 10, it is possible to avoid a short-circuit failure between the adjacent connection terminals 4 even if the conductive particulates 22 lie in a row.

A condition under which the conductive particulates 22 held between the connection terminals 4 of the substrate 2 and the terminals to be connected 3A of the mounted components 3 pierce through the cover layer 10 according to the press contact of the substrate 2 and the mounted component 3 can be experimentally set according to a relative relation between hardness, a particle diameter and a form of the conductive particulates 22, and a material and film thickness of the cover layer 10. As one condition, it is preferable that the diameter of the conductive particulates 22 is larger than the layer thickness of the cover layer 10. However, by providing fine protrusions on the surfaces of the connection terminals 4 or the surfaces of the terminals to be connected 3A, the conductive particulates 22 held between the connection terminals 4 and the terminals to be connected 3A can pierce through the cover layer 10 even if the condition is not satisfied.

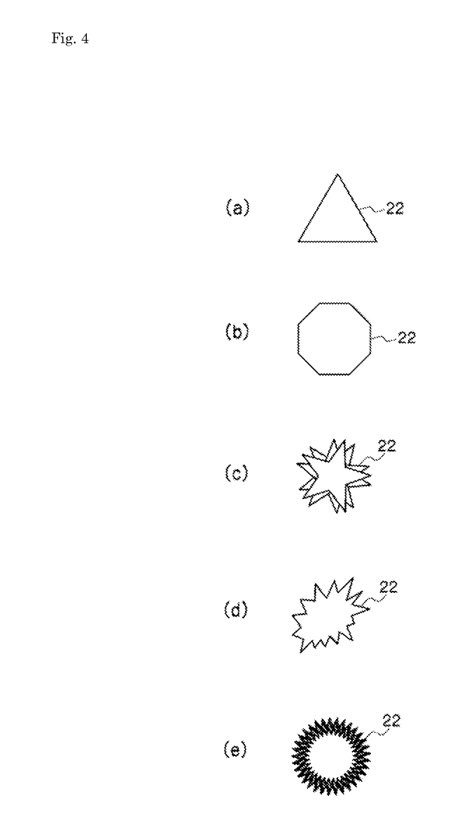

As one condition of the form of the conductive particulate 22, the conductive particulate 22 preferably has corners on the surface or in the entire shape of the conductive particulate 22. FIG. 4 schematically shows preferred form examples of the conductive particulate 22. In the examples shown in FIGS. 4(a) and 4(b), the entire shape is a triangular shape or a polygonal shape. The shape has corners in the entire shape. In the examples shown in FIGS. 4(c), 4(d) and 4(e), the entire shape is a shape having protrusions on the surface. The shape has partial corners on the surface.

A specific configuration example of the organic EL element 1U is explained below.

The substrate 2 is light transmissive and is formed by a base material that can support the organic EL element 1U such as glass or plastics. As a transparent conductive film layer forming the lower electrode 11, a transparent metal oxide such as an ITO (Indium Tin Oxide), an IZO (Indium Zinc Oxide), a zinc oxide transparent conductive film, an SnO₂ transparent conductive film, or a titanium dioxide transparent conductive film can be used.

When the lower electrode 11 is patterned and formed as a plurality of electrodes, the insulating layer 14 for securing insulation properties among the electrodes is provided. As the insulating layer 14, a material such as polyimide resin, acrylic resin, silicon oxide, or silicon nitride is used. As the formation of the insulating layer 14, after the material of the insulating layer 14 is film-formed on the substrate 2 on which the lower electrode 11 is patterned and formed, patterning for forming an opening for forming a light-emitting region for each of the organic EL elements 1U on the lower electrode 11 is performed. Specifically, a film is formed on the substrate 2, on which the lower electrode 11 is formed, to be applied in predetermined thickness by a spin coat method. Exposure treatment and development treatment are applied to the film using an exposure mask, whereby a layer of the insulating layer 14 having an opening pattern shape of the organic EL element 1U is formed. The insulating layer 14 is formed to fill spaces among the patterns of the lower electrode 11 and partially cover side end portions of the lower electrode 11. When the organic EL elements 1U are arranged in a dot matrix shape, the insulating layer 14 is formed in a lattice shape.

In order to form the patterns of the upper electrodes 13 without using a mask or the like or in order to completely electrically insulate the upper electrodes 13 adjacent to each other, the partition walls 15 are formed in a stripe shape in a direction orthogonal to the lower electrode 11. Specifically, after an insulating material such as photosensitive resin is applied and formed on the insulating layer 14 by the spin coat method or the like in film thickness larger than a sum of the film thicknesses of the organic layer 12 and the upper electrode 13 forming the organic EL element 1U, an ultraviolet ray or the like is irradiated on the photosensitive resin film via a photo-mask having stripe-like patterns crossing the lower electrode 11. The partition walls 15, side portions of which have downward taper surfaces, are formed making use of a difference in development speed caused by a difference in an exposure amount in the thickness direction of the layers.

The organic layer 12 has a laminated structure of light-emitting functional layers including a light-emitting layer. When one of the lower electrode 11 and the upper electrode 13 is set as an anode and the other is set as a cathode, a hole injection layer, a hole transport layer, a light-emitting layer, an electron transport layer, an electron injection layer, and the like are selectively formed in order from the anode side. Vacuum vapor deposition or the like is used as dry film formation of the organic layer 12. Application or various printing methods are used as dry film formation.

A formation example of the organic layer 12 is explained below. For example, first, NPB (N, N-di(naphtalence)-N,N-dipheneyl-benzidene) is formed as a hole transport layer. The hole transport layer has a function of transporting holes injected from the anode to the light-emitting layer. The hole transport layer may be one laminated layer or may be two or more laminated layers. As the hole transport layer, one layer may be formed by a plurality of materials rather than film formation by a single material. A guest material having high charge grant (acceptance) properties may be doped in a host material having a high charge transport ability.

Subsequently, a light-emitting layer is formed on the hole transport layer. As an example, light-emitting layers of red (R), green (G), and blue (B) are formed in respective film forming regions using a mask for selective painting according to resistance heating vapor deposition. As red (R), an organic material that emits red light such as a styryl dye such as DCM1 (4-(dicyanomethylene)-2-methyl-6-(4′-dimethylamino styryl)-4H-pyran) is used. As green (G), an organic material that emits green light such as an aluminum quinolinol complex (Alq3) is used. As blue (B), an organic material that emits blue light such as a distyryl derivative or a triazole derivative is used. Naturally, the light-emitting layers may be formed of other materials or may be formed in a host-guest system layer structure. A light emitting form may be a form using a fluorescent light-emitting material or using a phosphorescence light-emitting material.

The electron transport layer formed on the light-emitting layer is formed by various film forming method such as the resistance heating vapor deposition using various materials such as an aluminum quinolinol complex (Alq3). The electron transport layer has a function of transporting electrons injected from the cathode to the light-emitting layer. The electron transport layer may include one laminated layer or a multilayer structure of two or more laminated layers. As the electron transport layer, one layer may be formed by a plurality of materials rather than film formation by a single material. A guest material having high charge grant (acceptance) properties may be doped in a host material having a high charge transport ability.

When the upper electrode 13 formed on the organic layer 12 is the cathode, a material (metal, a metal oxide, a metal fluoride, an alloy, etc.) having a work function (e.g., equal to or smaller than 4 eV) smaller than a work function of the anode can be used. Specifically, a meal film of aluminum (Al), indium (In), magnesium (Mg), or the like, an amorphous semiconductor such as doped polyaniline or doped polyphenylene vinylene, an oxide such as Cr₂O₃, NiO, or Mn₂O₅ can be used. As a structure, a single layer structure by a metal material, a laminated structure such as LiO₂/Al, and the like can be adopted.

In the sealing member 6 that seals the organic EL element 1U, a glass substrate or a metal substrate is used, as the sealing substrate 6A that performs the hollow sealing. As an example, a single layer or a multilayer film of metal, a silicon oxide, a nitride, or an oxynitride formed by atomic layer deposition can be used, as the sealing film 6B for performing the film sealing. For example, an aluminum oxide film (e.g., an Al₂O₂ or Al₂O₃ film) obtained by reaction of alkyl metal such as TMA (trimethylaluminum), TEA (triethylaluminum) or DMAH (dimethylaluminum hydride) and water, oxygen or alcohol, a silicon oxide film (e.g., SiO₂ film) obtained by reaction of a vaporized gas of a silicon material and a vaporized gas of water, or the like can be used.

As explained above, a proper material and a proper film thickness of the cover layer 10 are selected according to a relation among hardness, a diameter, and a form of the conductive particulates 22. When the cover layer 10 is formed by the sealing film 6B, the cover layer 10 preferably includes an inorganic substance, in particular, an aluminum oxide film such as Al₂O₃. The cover layer 10 is preferably a layer formed by the atomic layer deposition (ALD).

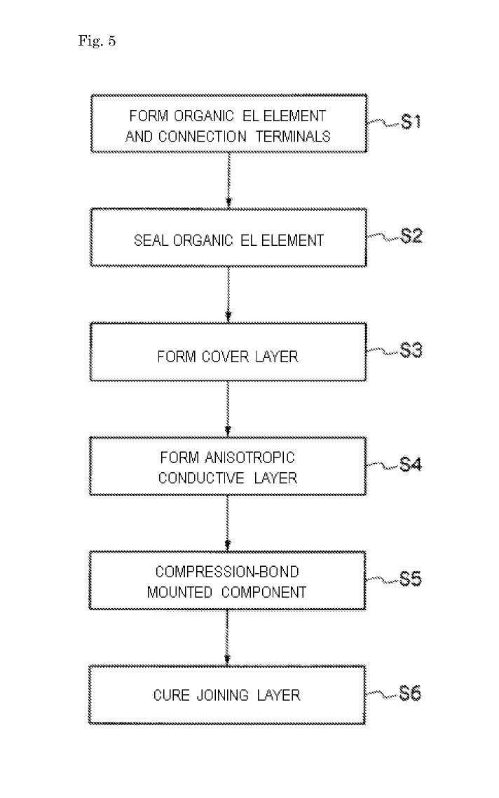

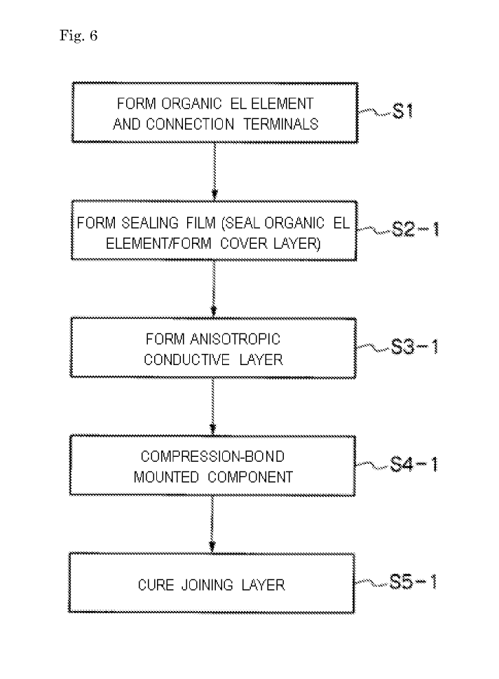

FIG. 5 and FIG. 6 are explanatory diagrams showing a manufacturing method for the organic EL device according to the embodiment of the present invention.

In an example shown in FIG. 5, a manufacturing process corresponding to the form example shown in FIG. 2(a) is shown. First, the organic EL elements 1U are formed on the substrate 2 and the connection terminals 4 connected to the electrodes (the upper electrodes 11 and the lower electrodes 13) of the organic EL elements 1U are formed in the connection space 2b on the substrate 2 (S1 step). Subsequently, sealing of the organic EL elements 1U is performed (S2 step). In this step, the substrate 2 and the sealing substrate 6A are stuck together to seal the organic EL elements 1U in the sealing space 6S.

Subsequently, the cover layer 10 is formed in the connection space 2b (S3 step). The anisotropic conductive layer 20 is formed on the cover layer 10 (S4 step). When the anisotropic conductive layer 20 is formed integrally with the mounted component 3 such as a flexible wiring board, the formation of the anisotropic conductive layer 20 is performed by arranging the terminal to be connected 3A of the mounted component 3 in the connection space 2b. When the anisotropic conductive layer 20 is separately formed, an anisotropic conductive film (ACF) is arranged in the connection space 2b in which the cover layer 10 is formed. Alternatively, the joining layer 21, in which the conductive particulates 22 are dispersed, is applied to the connection space 2b in which the cover layer 10 is formed or, after the joining layer 21 is applied, the conductive particulates 22 are dispersed in the joining layer 21.

Subsequently, in the connection space 2b, the substrate 2 and the mounted component 3 are compression-bonded (S5 step). When the joining layer 21 of the anisotropic conductive layer 20 interposed between the substrate 2 and the mounted component 3 is thermofusible, the substrate 2 and the mounted component 3 are compression-bonded while being heated. When the joining layer 21 is light curing resin, the substrate 2 and the mounted component 3 are compression-bonded under a condition that resin is not cured. According to the compression bonding, the cover layer 10 is pierced through by the conductive particulates 22 held between the connection terminals 4 of the substrate 2 and the terminal to be connected 3A of the mounted component 3. The connection terminals 4 and the terminal to be connected 3A are electrically connected via the conductive particulates 22 in a connection region where the connection terminals 4 and the terminal to be connected 3A face each other. Thereafter, the joining layer 21 is cured (S6 step). When the joining layer 21 is a light curing resin, light such as an ultraviolet ray is irradiated on the joining layer 21 to cure the joining layer 21 while a compression-bonded state is maintained.

In an example shown in FIG. 6, a manufacturing process corresponding to the form example shown in FIG. 2(b) is shown. First, as in the example explained above, the organic EL elements 1U are formed on the substrate 2 and the connection terminals 4 connected to the electrodes (the upper electrodes 11 and the lower electrodes 13) of the organic EL elements 1U are formed in the connection space 2b on the substrate 2 (S1 step). Subsequently, the sealing film 6B for sealing the organic EL elements 1U is formed over the entire substrate. In this case, the sealing of the organic EL elements 1U is performed by the sealing film 6B and the cover layer 10 is formed in the connection space 2b by the sealing film 6B. An anisotropic conduction film forming step (S3-1), a mounted component compression-bonding step (S4-1), and a joining layer curing step (S5-1) after S2-1 are the same as the S4 step, the S5 step, and the S6 step explained above.

According to the manufacturing method shown in FIG. 6, when the sealing of the organic EL elements 1U is performed by the sealing film 6B, a step of exposing the connection terminals 4 in the connection space 2b is unnecessary. Consequently, it is possible to reduce a takt time required for exposure of the connection terminals 4 in the connection space 2b and eliminate a facility required for the step. Therefore, it is possible to reduce the manufacturing process for the organic EL device 1 implementing film sealing and reduce manufacturing costs.

The embodiments of the present invention are explained in detail above with reference to the drawings. However, a specific configuration is not limited to the embodiments. A change and the like of design within a range not departing from the spirit of the present invention are also included in the present invention. The description contents of the embodiments shown in the figures can be combined as long as there is no particular contradiction or problems in the purposes, the configurations, and the like of the embodiments. The described contents of the figures could be independent embodiments. The embodiments of the present invention are not limited to one embodiment obtained by combining the figures.

What is claimed is:

1. An organic EL device comprising:
a substrate;
one or a plurality of organic EL elements formed on said substrate;
a plurality of connection terminals provided on said substrate and electrically connected to electrodes of said organic EL elements;
an insulating cover layer covering said connection terminals and said substrate between said connection terminals; and
a mounted component mounted via an anisotropic conducive layer and including terminals to be connected electrically to said connection terminals, wherein
said anisotropic conductive layer includes conductive particulates that electrically connect said connection terminals and said terminals to be connected, and
said conductive particulates electrically connect said connection terminals and said terminals to be connected piercing through said cover layer.

2. The organic EL device according to claim 1, wherein said anisotropic conductive layer includes an insulating joining layer that physically joins said substrate and said mounted component, and said conductive particulates are dispersed in said joining layer.

3. The organic EL device according to claim 2, wherein, due to compression bonding of said substrate and said mounted component, said conductive particulates pierce through said cover layer and electrically connect said connection terminals and said terminals to be connected.

4. The organic EL device according to claim 3, wherein said connection terminals and said cover layer are arranged in a connection space in which said substrate and said mounted components are connected.

5. The organic EL device according to claim 4, wherein said cover layer is formed by a sealing film that seals said organic EL element between said sealing film and said substrate.

6. The organic EL device according to claim 5, wherein said cover layer includes an inorganic substance.

7. The organic EL device according to claim 6, wherein said cover layer includes an aluminum oxide film.

8. The organic EL device according to claim 5, wherein said cover layer is a layer formed by atomic layer deposition (ALD).

9. The organic EL device according to claim 3, wherein said anisotropic conductive layer is a thermo-compression bonding anisotropic conductive film.

10. The organic EL device according to claim 2, wherein said joining layer of said anisotropic conductive layer is light curing resin.

11. The organic EL device according to claim 1, wherein a diameter of said conductive particulate is larger than thickness of said cover layer.

12. The organic EL device according to claim 11, wherein said conductive particulate has corners on a surface or in an entire shape.

13. The organic EL device according to claim 1, wherein said connection terminal is a laminated structure of a plurality of layers.

14. A manufacturing method for an organic EL device comprising:
a step of forming an organic EL element on a substrate and forming, in a connection space on said substrate, a connection terminal connected to an electrode of said organic EL element;
a step of forming an insulating cover layer covering said connection terminal and said substrate in said connection space; and
a mounting step of mounting a mounted component in said connection space via an anisotropic conductive layer, wherein
in said mounting step, with said substrate and said mounted components being compression-bonded, conductive particulates of said anisotropic conductive layer electrically connect said connection terminal and a terminal to be connected of said mounted component piercing through said cover layer.

15. A manufacturing method for an organic EL device comprising:
a step of forming an organic EL element on a substrate and forming, in a connection space on said substrate, a connection terminal connected to an electrode of said organic EL element;
a step of forming an insulating cover layer that covers said connection terminals and said substrate in said connection space by forming a sealing film that seals said organic EL element between said sealing film and said substrate with said sealing film,; and
a mounting step of mounting a mounted component in said connection space via an anisotropic conductive layer, wherein
in said mounting step, with said substrate and said mounted components being compression-bonded, conductive particulates of said anisotropic conductive layer electrically connect said connection terminal and a terminal to be connected of said mounted component piercing through said cover layer

16. An organic EL device comprising:
a substrate;
one or a plurality of organic EL elements formed on said substrate;
a plurality of connection terminals provided on said substrate and electrically connected to electrodes of said organic EL elements;
a sealing film formed by atomic layer deposition (ALD), said sealing film sealing said organic EL elements and said plurality of terminals; and
a mounted component mounted via an anisotropic conducive layer and including terminals to be connected electrically to said connection terminals, wherein
said anisotropic conductive layer includes conductive particulates having a diameter larger than a diameter of said sealing film, said conductive particulates electrically connecting said connection terminals and said terminals to be connected, and
said plurality of connection terminals and said conductive particulates come into contact with each other piercing through said sealing film.

17. The organic EL device according to claim 1, wherein said sealing film is formed over said entire substrate.
